(19) United States
(12) Patent Application Publication
(10) Pub. No.: US 2025/0372388 A1
(43) Pub. Date: Dec. 4, 2025

(54) METHOD FOR GERMANIUM ETCHING

(71) Applicant: UIF (University Industry Foundation), Yonsei University, Seoul (KR)

(72) Inventors: Jungwoo OH, Incheon (KR); Haekyun BONG, Incheon (KR)

(21) Appl. No.: 19/219,627

(22) Filed: May 27, 2025

(30) Foreign Application Priority Data
May 30, 2024 (KR) 10-2024-0070621
Apr. 16, 2025 (KR) 10-2025-0049380

(51) Int. Cl. H01L 21/3063

(52) U.S. Cl. CPC H01L 21/3063

(57) ABSTRACT

A method for germanium etching includes the steps of: preparing a germanium substrate; forming a metal pattern layer for etching on an upper surface of the germanium substrate; connecting a positive electrode of a battery to the metal pattern layer and a negative electrode of the battery to a metal material; placing the germanium substrate on which the metal pattern layer is formed into a tank filled with an electrolyte solution; and applying power to the battery to perform etching.

### CROSS-REFERENCE TO RELATED APPLICATIONS

This application claims priority under 35 U.S.C. § 119(a) to Korean Patent Application No. 10-2024-0070621 filed with the Korean Intellectual Property Office on May 30, 2024, and Korean Patent Application No. 10-2025-0049380 filed with the Korean Intellectual Property Office on Apr. 16, 2025. The disclosures of the above patent applications are incorporated herein in by reference in their entirety.

### BACKGROUND

### 1. Technical Field

The present disclosure relates to a method for germanium etching, and more particularly, to a method for germanium etching capable of alleviating surface damage when etching germanium by applying an anodic etching method to a metal-assisted chemical etching method.

### 2. Description of the Related Art

Integrated circuits are made possible by processes that create intricately patterned layers of material on substrate surfaces. Creating patterned material on a substrate requires controlled methods for removing the exposed material. Chemical etching is used for a variety of purposes, including transferring a pattern in a photoresist into underlying layers, thinning layers, or thinning the lateral dimensions of features already present on a surface.

Etching processes can be designated as wet or dry, based on the materials used in the process. One wet etching method is metal-assisted chemical etching.

Metal-assisted chemical etching of semiconductors is a wet-based anisotropic etching technique performed in a solution consisting of an acid and an oxidizer, and is a technique to improve the cost and surface damage problems of dry etching. This technique has been mainly studied for use on silicon and gallium arsenide substrates, but its application to germanium has been limited.

Therefore, research is needed on an etching method that can alleviate surface damage when etching germanium.

### SUMMARY OF THE INVENTION

An object of the present disclosure is to provide a method for germanium etching capable of alleviating surface damage when etching germanium by applying an anodic etching method to a metal-assisted chemical etching method.

Another object of the present disclosure is to provide a method for germanium etching capable of increasing the convenience of etching, by forming an electrode connection layer on the lower surface of a germanium substrate separately from a metal pattern layer for etching.

In order to achieve the above object, according to one embodiment of the present disclosure, a method for germanium etching is disclosed, characterized by including the steps of: providing a germanium substrate; forming a metal pattern layer for etching on an upper surface of the germanium substrate; connecting a positive electrode of a battery to the metal pattern layer and connecting a negative electrode of the battery to a metal material; immersing the germanium substrate on which the metal pattern layer is formed in an electrolyte solution; and applying power to the battery to perform etching.

In order to achieve the above object, according to one embodiment of the present disclosure, a method for germanium etching is disclosed, including the steps of: providing a germanium substrate; forming a metal pattern layer for etching on an upper surface of the germanium substrate; forming a wall on an upper surface of the germanium substrate on which the metal pattern layer is formed so as to contain an electrolyte solution; injecting an electrolyte solution into the wall; connecting a positive electrode of a battery to the metal pattern layer and connecting a negative electrode of the battery to a metal material; immersing the metal material in the electrolyte solution; and applying power to the battery to perform etching.

In order to achieve the above object, according to one embodiment of the present disclosure, a method for germanium etching is disclosed, including the steps of: providing a germanium substrate; forming a metal pattern layer for etching on an upper surface of the germanium substrate; forming an electrode connection layer on a lower surface of the germanium substrate; forming a wall on an upper surface of the germanium substrate, on which a metal pattern layer is formed on an upper surface so as to contain an electrolyte solution and an electrode connection layer is formed on a lower surface; injecting an electrolyte solution into the wall; connecting a positive electrode of a battery to the electrode connection layer formed on a lower surface of the germanium substrate and connecting a negative electrode of the battery to a metal material; immersing the metal material in the electrolyte solution; and applying power to the battery to perform etching.

A method for germanium etching according to one embodiment of the present disclosure can reduce surface damage when etching a germanium substrate by applying an anodic etching method to a metal-assisted chemical etching method.

According to one embodiment of the present disclosure, the range of application of the technology can be expanded and process costs can be reduced by using non-precious metals such as Ni, Cr, and Ti instead of precious metals that are essential in metal-assisted chemical etching.

According to one embodiment of the present disclosure, etching can be performed using an electrolyte without acids and oxidizing agents used in traditional metal-assisted chemical etching, thereby improving etching quality compared to existing etching methods.

According to one embodiment of the present disclosure, an electrode connection layer is formed on the lower surface of a germanium substrate separately from a metal pattern layer for etching, so that etching can be performed more simply.

### BRIEF DESCRIPTION OF THE DRAWINGS

FIG. 1 is a flow chart showing an etching process related to the first embodiment of the present disclosure.

FIG. 2 is an etching schematic diagram for explaining the etching process of FIG. 1.

FIG. 3 is a flow chart showing an etching process related to the second embodiment of the present disclosure.

FIG. 4 is an etching schematic diagram for explaining the etching process of FIG. 3.

FIG. 5 is a flow chart showing an etching process related to the third embodiment of the present disclosure.

FIG. 6 is an etching schematic diagram for explaining the etching process of FIG. 5.

FIG. 7 is a drawing showing an example in which a plurality of patterns are formed among metal pattern layers related to one embodiment of the present disclosure.

FIG. 8 is a drawing showing an etched shape according to the type of electrolyte solution and metal related to one embodiment of the present disclosure.

FIG. 9 is a drawing showing an etched shape according to the applied voltage related to one embodiment of the present disclosure.

FIG. 10 is a drawing showing an etched shape according to an etching time related to one embodiment of the present disclosure.

### DETAILED DESCRIPTION OF THE INVENTION

Hereinafter, a method for germanium etching related to an embodiment of the present disclosure will be described with reference to the drawings.

It is to be understood that, unless obviously and clearly noted or specified otherwise within the specification, singular forms of the terms used herein may include plural forms of the corresponding terms. In the description of the invention, the terms “consist(s) of” or “include(s) (or comprise(s))” should not be interpreted or understood as including, without exception, all of the plurality of elements (or components) or the plurality of steps disclosed in the description of the invention. In other words, it should be understood that some (or part) of the elements (or components) or some (or part) of the steps may not be included, or that additional elements (or components) or steps may be further included in the present invention.

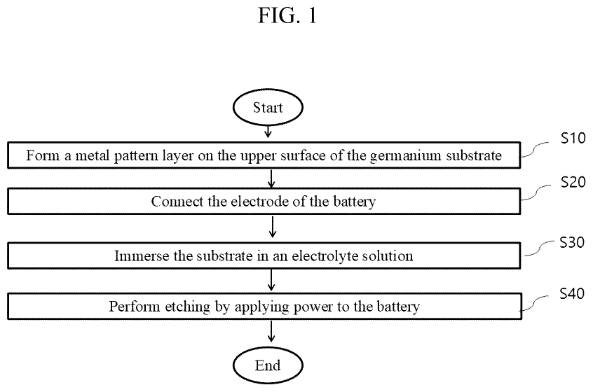

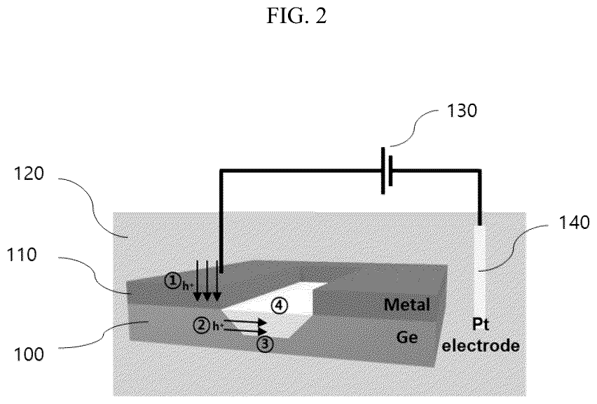

FIG. 1 is a flow chart showing an etching process related to the first embodiment of the present disclosure, and FIG. 2 is an etching schematic diagram for explaining the etching process of FIG. 1.

First, a germanium substrate 100 to be etched may be prepared. A metal pattern layer 110 may be formed on the upper surface of the prepared germanium substrate 100 (S10). The germanium substrate 100 can be etched even in an electrolyte solution without an acid or an oxidizing agent. Since the electrolyte solution does not contain an acid or an oxidizing agent, the metal pattern layer 110 may be formed of a non-precious metal such as Ni, Cr, or Ti, rather than a precious metal that is essentially used in metal-assisted chemical etching.

The electrode of the battery 130 to which power is supplied may be connected (S20). The positive electrode of the battery 130 may be connected to the metal pattern layer 110, and the negative electrode of the battery 130 may be connected to a metal material 140. The metal material 140 may include, for example, Pt as a material that allows current to flow.

Then, the germanium substrate 100 on which the metal pattern layer 110 is formed may be immersed in an electrolyte solution 120 (S30). The electrolyte solution 120 may be filled in a water tank (not shown).

The electrolyte solution 120 may not contain an acid or an oxidizing agent. A solution containing any one of NaOH, KCl, and KOH may be used as the electrolyte solution 120. The electrolyte solution 120 may be used as an etching solution.

When the negative electrode of the battery 130 and the metal material 140 are connected, the metal material 140 may also be immersed in the electrolyte solution 120.

Then, by applying power to the battery 130 to allow current to flow, etching may be performed (S40).

The portion of the upper surface of the germanium substrate 100 where the metal pattern layer 110 is formed is not etched, and only the portion where the metal pattern layer 110 is not formed is etched.

The mechanism of the germanium etching method related to the first embodiment of the present disclosure is as follows. Holes are injected into the metal by an external voltage (\textcircled{1}). Then, the holes diffuse into the germanium (Ge) region exposed to the electrolyte solution (\textcircled{2}). Germanium (Ge) reacts with the holes to generate an oxide (GeO₂) (\textcircled{3}). Then, the generated oxide (GeO₂) is dissolved in water (\textcircled{4}). Then, the etching process is performed by repeating the steps \textcircled{1} to \textcircled{4}.

The above-described mechanism may be applied identically or similarly to the second and third embodiments of the present disclosure to be described below.

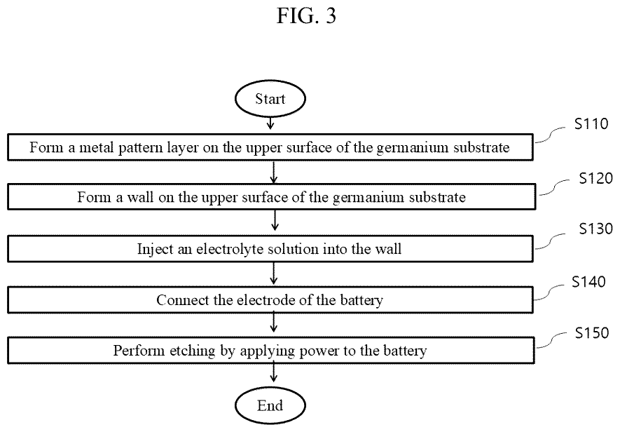

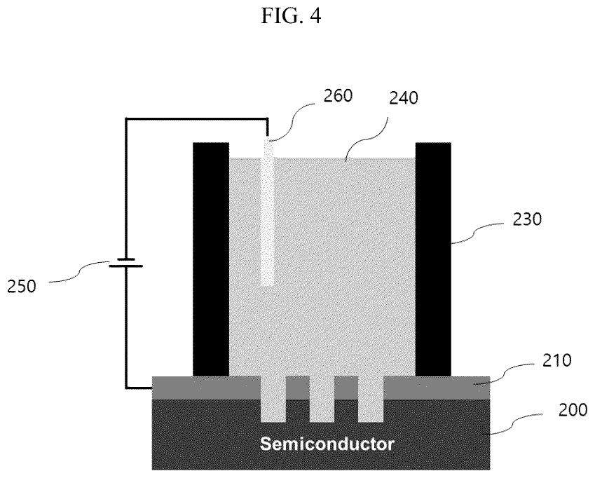

FIG. 3 is a flow chart showing an etching process related to the second embodiment of the present disclosure, and FIG. 4 is an etching schematic diagram for explaining the etching process of FIG. 3.

First, a germanium substrate 200 to be etched may be prepared. A metal pattern layer 210 may be formed on the upper surface of the prepared germanium substrate 200 (S110). The germanium substrate 200 can be etched even in an electrolyte solution without an acid or an oxidizing agent. Since the electrolyte solution does not contain an acid or an oxidizing agent, the metal pattern layer 210 may be formed of a non-precious metal such as Ni, Cr, or Ti, rather than a precious metal that is essentially used in metal-assisted chemical etching.

After the metal pattern layer 210 is formed on the upper surface of a germanium substrate 200, a wall may be formed on the upper surface of the germanium substrate 200 on which the metal pattern layer 210 is formed so that an electrolyte solution can be contained (S120). The wall 230 may be formed in a pillar shape. Plastic, glass, or the like may be used as a material for the wall 230. When the wall 230 is formed, a type of container containing an electrolyte solution can be formed. The upper surface of the germanium substrate 200 can become the bottom surface of the container, and the wall 230 can serve as a side wall surrounding the edge.

Once the wall 230 is formed, an electrolyte solution 240 may be injected into the wall 230 (S130). When the electrolyte solution 240 is injected, only the upper surface of the germanium substrate 200 on which the metal pattern layer 210 is formed can come into contact with the electrolyte solution 240. The electrolyte solution 240 may not contain an acid or an oxidizing agent. A solution containing any one of NaOH, KCl, and KOH may be used as the electrolyte solution 240. The electrolyte solution 240 may be used as an etching solution.

Then, the electrode of the battery 250 to which power is supplied may be connected (S140). The positive electrode of the battery 250 may be connected to the metal pattern layer 210, and the negative electrode of the battery 250 may be connected to the metal material 260. The metal material 260 may include, for example, Pt as a material that allows current to flow.

When the negative electrode of the battery 250 and the metal material 260 are connected, the metal material 260 may be immersed in the electrolyte solution 240.

Then, by applying power to the battery 250 to allow current to flow, etching may be performed (S150).

The portion of the upper surface of the germanium substrate 200 where the metal pattern layer 210 is formed is not etched, and only the portion where the metal pattern layer 210 is not formed is etched.

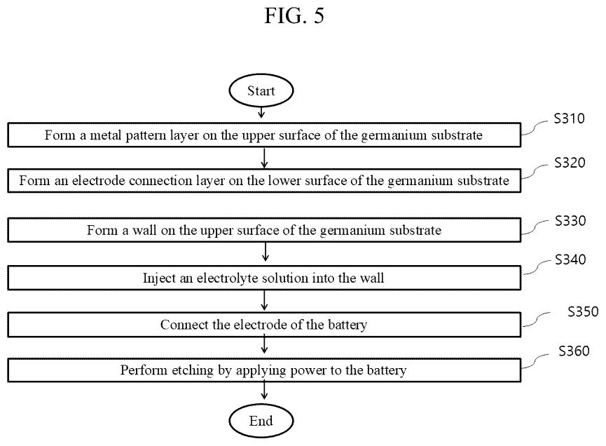

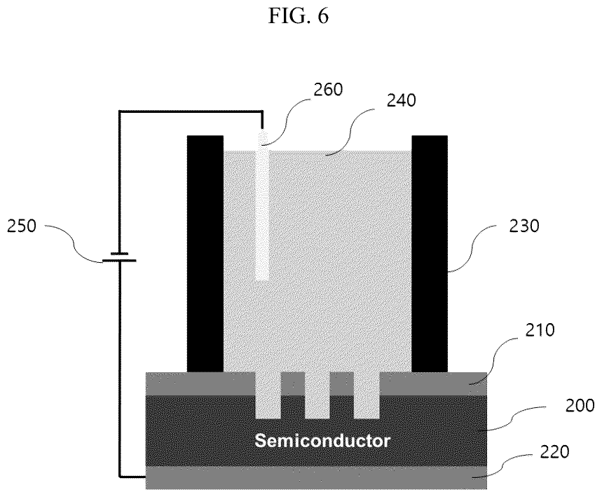

FIG. 5 is a flow chart showing an etching process related to the third embodiment of the present disclosure, and FIG. 6 is an etching schematic diagram for explaining the etching process of FIG. 5.

First, a germanium substrate 200 to be etched may be prepared. A metal pattern layer 210 may be formed on the upper surface of the prepared germanium substrate 200 (S310). The germanium substrate 200 can be etched even in an electrolyte solution without an acid or an oxidizing agent. Since the electrolyte solution does not contain an acid or an oxidizing agent, the metal pattern layer 210 may be formed of a non-precious metal such as Ni, Cr, or Ti, rather than a precious metal that is essentially used in metal-assisted chemical etching.

Then, an electrode connection layer 220 may be formed on the lower surface of the germanium substrate 200 (S320).

The electrode connection layer 220 may be made of a metal layer. For example, the electrode connection layer 220 may be made of a non-precious metal such as Ni, Cr, or Ti.

After forming a metal pattern layer 210 on the upper surface of a germanium substrate 200, and an electrode connection layer 220 on the lower surface, a wall may be formed on the upper surface of the germanium substrate 200 on which the metal pattern layer 210 is formed so that an electrolyte solution can be contained (S330). The wall 230 may be formed in a pillar shape. Plastic, glass, or the like may be used as the material of the wall 230. When the wall 230 is formed, a kind of container containing an electrolyte solution can be formed. The upper surface of the germanium substrate 200 may become the bottom surface of the container, and the wall 230 may serve as a side wall surrounding the edge.

Once the wall 230 is formed, an electrolyte solution 240 may be injected into the wall 230 (S340). When the electrolyte solution 240 is injected, only the upper surface of the germanium substrate 200 on which the metal pattern layer 210 is formed can come into contact with the electrolyte solution 240. The electrolyte solution 240 may not contain an acid or an oxidizing agent. A solution containing any one of NaOH, KCl, and KOH may be used as the electrolyte solution 240. The electrolyte solution 240 may be used as an etching solution.

Then, the electrode of the battery 250 to which power is supplied may be connected (S350). The positive electrode of the battery 250 may be connected to the electrode connection layer 220 rather than the metal pattern layer 210, and the negative electrode of the battery 250 may be connected to the metal material 260. The metal material 260 may include, for example, Pt as a material that allows current to flow.

When the negative electrode of the battery 250 and the metal material 260 are connected, the metal material 260 may be immersed in the electrolyte solution 240.

Then, by applying power to the battery 250 to allow current to flow, etching may be performed (S360).

The portion of the upper surface of the germanium substrate 200 where the metal pattern layer 210 is formed is not etched, and only the portion where the metal pattern layer 210 is not formed is etched.

Meanwhile, according to one embodiment of the present disclosure, the metal pattern layer 210 may be formed of a plurality of patterns formed spaced apart from each other.

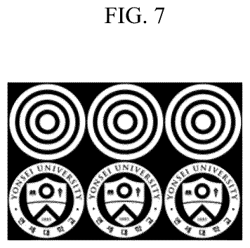

FIG. 7 is a drawing showing an example in which a plurality of patterns are formed among metal pattern layers related to one embodiment of the present disclosure.

In FIG. 7, black represents a metal pattern, and white represents a germanium substrate. When etching a pattern like FIG. 5, in the case of the second embodiment of the present disclosure, electrodes must be connected to each pattern, but in the case of the third embodiment of the present disclosure, the same etching effect can be achieved even when the positive electrode of the battery 250 is connected to the electrode connection layer 220 instead of the metal pattern layer 210. That is, in the case of the etching method of the third embodiment of the present disclosure, the etching method is less complicated and more convenient than that of the second embodiment of the present disclosure.

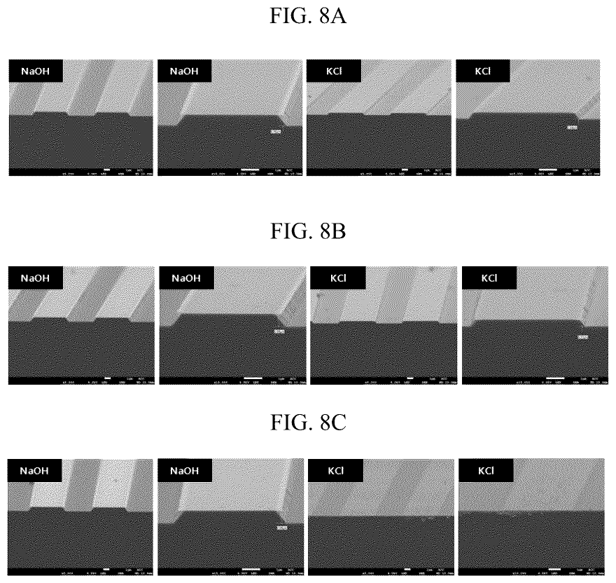

FIG. 8 is a drawing showing an etched shape according to the type of electrolyte solution and metal related to the third embodiment (the embodiment of FIGS. 5 and 6) of the present disclosure.

FIG. 8A is an etching photograph when Ti is used as a metal pattern layer 210, FIG. 8B is an etching photograph when Cr is used as a metal pattern layer 210, and FIG. 8C is an etching photograph when Ni is used as a metal pattern layer 210. As can be seen from the drawings, etching is performed well even when a non-precious metal, not a precious metal, is used as a metal pattern layer 210.

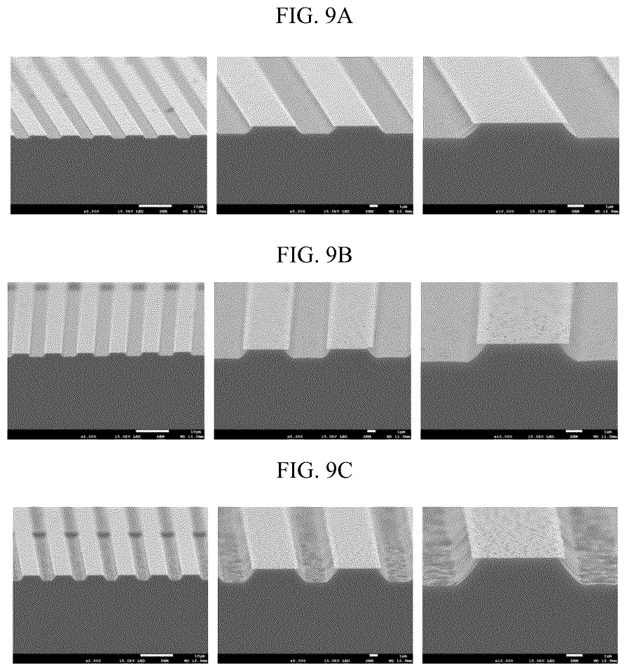

FIG. 9 is a drawing showing an etched shape according to the applied voltage related to one embodiment of the present disclosure.

FIG. 9A is an etching photograph when a voltage of 0.9V is applied to the battery for 10 minutes, FIG. 9B is an etching photograph when a voltage of 1.2V is applied to the battery for 10 minutes, and FIG. 9C is an etching photograph when a voltage of 1.5V is applied to the battery for 10 minutes. As can be seen from the drawings, the etching speed increases as the applied voltage increases.

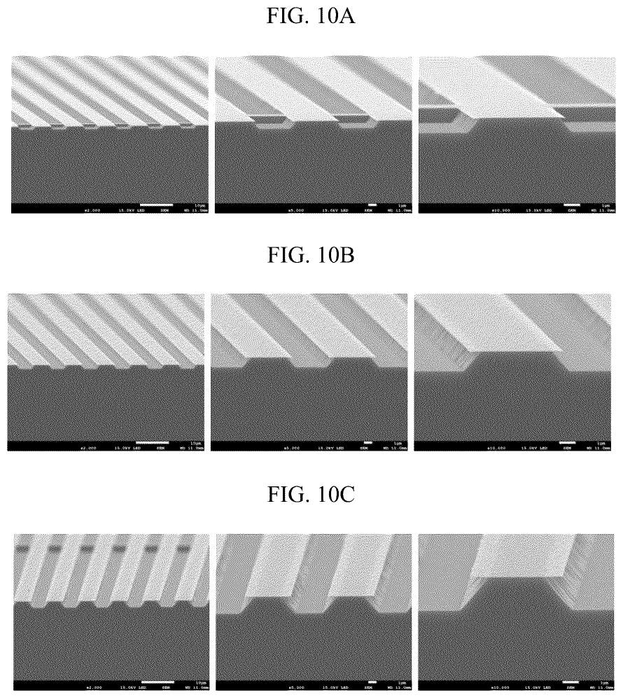

FIG. 10 is a drawing showing an etched shape according to an etching time related to one embodiment of the present disclosure.

FIG. 10A is an etching photograph when a voltage of 0.5V is applied to the battery for 20 minutes, FIG. 10B is an etching photograph when a voltage of 0.5V is applied to the battery for 30 minutes, and FIG. 10C is an etching photograph when a voltage of 0.5V is applied to the battery for 60 minutes. As can be seen from the drawings, the etching depth becomes deeper as the etching time increases.

As described above, the method for germanium etching according to one embodiment of the present disclosure can reduce surface damage when etching a germanium substrate by applying an anodic etching method to a metal-assisted chemical etching method.

According to one embodiment of the present disclosure, the range of application of the technology can be expanded and process costs can be reduced by using non-precious metals such as Ni, Cr, and Ti instead of precious metals that are essential in metal-assisted chemical etching.

According to one embodiment of the present disclosure, etching can be performed using an electrolyte without acids and oxidizing agents used in traditional metal-assisted chemical etching, thereby improving etching quality compared to existing etching methods.

According to one embodiment of the present disclosure, an electrode connection layer is formed on the lower surface of a germanium substrate separately from a metal pattern layer for etching, so that etching can be performed more simply.

The configurations and methods for germanium etching in the aforesaid embodiments may not be limitedly applied, but such embodiments may be configured by a selective combination of all or part of each embodiment so as to derive many variations.

What is claimed is:

1. A method for germanium etching, characterized by including the steps of:
providing a germanium substrate;
forming a metal pattern layer for etching on an upper surface of the germanium substrate;
connecting a positive electrode of a battery to the metal pattern layer and connecting a negative electrode of the battery to a metal material;
immersing the germanium substrate on which the metal pattern layer is formed in an electrolyte solution; and
applying power to the battery to perform etching.

2. The method for germanium etching according to claim 1,
wherein the electrolyte solution is a solution without acid or oxidizing agent.

3. The method for germanium etching according to claim 2,
wherein the electrolyte solution is a solution containing any one of NaOH, KCl, and KOH.

4. The method for germanium etching according to claim 2,
wherein the metal pattern layer is made of one of Ti, Cr and Ni.

5. The method for germanium etching according to claim 2,
wherein the metal material contains Pt.

6. A method for germanium etching, including the steps of:
providing a germanium substrate;
forming a metal pattern layer for etching on an upper surface of the germanium substrate;
forming a wall on the upper surface of the germanium substrate on which the metal pattern layer is formed so as to contain an electrolyte solution;
injecting the electrolyte solution into the wall;
connecting a positive electrode of a battery to the metal pattern layer and connecting a negative electrode of the battery to a metal material;
immersing the metal material in the electrolyte solution; and
applying power to the battery to perform etching.

7. The method for germanium etching according to claim 6,
wherein the electrolyte solution is a solution without acid or oxidizing agent.

8. The method for germanium etching according to claim 7,
wherein the electrolyte solution is a solution containing any one of NaOH, KCl, and KOH.

9. The method for germanium etching according to claim 7,
wherein the metal pattern layer is made of one of Ti, Cr and Ni.

10. The method for germanium etching according to claim 7,
wherein the metal material contains Pt.

11. A method for germanium etching, including the steps of:
providing a germanium substrate;
forming a metal pattern layer for etching on an upper surface of the germanium substrate;
forming an electrode connection layer on a lower surface of the germanium substrate;
forming a wall on the upper surface of the germanium substrate, on which the metal pattern layer is formed on the upper surface so as to contain an electrolyte solution and the electrode connection layer is formed on the lower surface;
injecting the electrolyte solution into the wall;
connecting a positive electrode of a battery to the electrode connection layer formed on the lower surface of the germanium substrate and connecting a negative electrode of the battery to a metal material;
immersing the metal material in the electrolyte solution; and
applying power to the battery to perform etching.

12. The method for germanium etching according to claim 11,
wherein the electrolyte solution is a solution without acid or oxidizing agent.

13. The method for germanium etching according to claim 12,
wherein the electrolyte solution is a solution containing any one of NaOH, KCl, and KOH.

14. The method for germanium etching according to claim 12,
wherein the metal pattern layer is made of one of Ti, Cr and Ni.

15. The method for germanium etching according to claim 12,
wherein the metal material contains Pt.

16. The method for germanium etching according to claim 12,
wherein the electrode connection layer is made of one of Ti, Cr and Ni.

17. The method for germanium etching according to claim 12,
wherein the step of forming the electrode connection layer includes the steps of:
applying an adhesive to the lower surface of the germanium substrate; and
forming the electrode connection layer on the adhesive.

18. The method for germanium etching according to claim 17,
wherein the adhesive is made of Ti.
